(19) United States
(12) Patent Application Publication
(10) Pub. No.: US 2021/0088593 A1
(43) Pub. Date: Mar. 25, 2021

(54) CHARGING REMINDING METHOD FOR RECHARGEABLE DEVICE AND MEMORY

(71) Applicant: Tymphany Acoustic Technology Limited, Taipei City (TW)

(72) Inventor: CHENG-YANG LIAO, TAIPEI CITY (TW)

(21) Appl. No.: 17/029,693

(22) Filed: Sep. 23, 2020

(30) Foreign Application Priority Data
Sep. 24, 2019 (CN) 201910904113.7

(51) Int. Cl. G01R 31/36; G01R 31/387

(52) U.S. Cl. CPC G01R 31/3646; G01R 31/387

(57) ABSTRACT

A charging reminder method for a rechargeable device and a memory includes calculating, by an external electronic device of the rechargeable device, the remaining battery power when the rechargeable device is turned off; obtaining, by the external electronic device, the remaining time until the battery reaches the over-discharge point according to the remaining battery power and the quiescent current when the rechargeable device is turned off; sending out, by the external electronic device, at least one charging reminder during the remaining time.

### CROSS REFERENCE TO RELATED APPLICATIONS

The present application claims priority to Chinese Patent Application No. CN 201910904113.7, which was filed on Sep. 24, 2019, the entire contents of which are hereby incorporated by reference.

### TECHNICAL FIELD

This application relates to a charging reminder method for a rechargeable device and a memory.

### BACKGROUND

Modern people have many 3C products, namely, computers, communications, and consumer electronics. These products usually need to be carried and used easily, therefore they need built-in batteries. However, when the product is not in use, it is often put aside and forgot to charge. After a period of time, the battery will be over-discharged, which will cause the battery to be unable to be recharged and become permanently unusable.

The existing charging reminder design always only reminds the user by flashing an indicator light or sounding when the product is low in battery. However, the users often do not notice these reminders. That is because the product is no longer in use at this time, and the users will not receive these reminders for not carrying this product with them.

### SUMMARY

This application provides a charging reminder method for a rechargeable device and a memory. The method can effectively remind users to charge rechargeable device which is not frequently used to avoid over-discharge of the battery.

The technical solution of this application is realized as follows.

The present application provides a charging reminder method for a rechargeable device. The method includes calculating, by an external electronic device of the rechargeable device, a remaining battery power when the rechargeable device is turned off; obtaining, by the external electronic device, a remaining time until a battery of the rechargeable device reaches an over-discharge point according to the remaining battery power and a quiescent current when the rechargeable device is turned off; sending out, by the external electronic device, at least one charging reminder during the remaining time.

In an embodiment of the present application, when the rechargeable device is turned off at reaching the turning off power, the remaining battery power is the battery power from the turning off power to the battery over-discharge point, the remaining time is a value obtained by dividing the remaining battery power by the quiescent current.

In an embodiment of the present application, when the rechargeable device is turned off at a power level higher than the turning off power, the remaining battery power at the time of turning off is calculated according to a percentage of the battery power at a previous turning off of the device, the remaining time is a value obtained by dividing the remaining battery power by the quiescent current.

In an embodiment of the present application, before calculating the remaining battery power when the rechargeable device is turned off, the method further includes: calculating, by the rechargeable device, a power value of the battery, and providing the power value to the external electronic device in response to an acquisition request of the external electronic device when the rechargeable device is not turned off; determining that the rechargeable device is turned off when the external electronic device cannot obtain the power value.

In an embodiment of the present application, before calculating the remaining battery power when the rechargeable device is turned off, the method further includes: sending out, by the external electronic device, at least one power value reminder when the rechargeable device is not turned off.

In an embodiment of the present application, the charging reminder is displayed on the display screen of the external electronic device in one or more manners of text, sound, picture, and light-emitting.

In an embodiment of the present application, the external electronic device is a mobile phone, the mobile phone and the rechargeable device communicate with each other wirelessly.

The present application further provides a memory, storing a program, the program is executed by an external electronic device of a rechargeable device to implement the following operations: calculating, by the external electronic device, a remaining battery power when the rechargeable device is turned off; obtaining, by the external electronic device, a remaining time until the battery reaches an over-discharge point according to the remaining battery power and a quiescent current when the rechargeable device is turned off; sending out, by the external electronic device, at least one charging reminder during the remaining time.

The above-mentioned technical solution of this application calculates the remaining power of the rechargeable device by an external electronic device of the rechargeable device, and reminds the user the remaining time of the battery before reaching the over-discharge. The present application can effectively remind the user to charge the rechargeable device that is not frequently used to avoid over-discharge of the battery.

### BRIEF DESCRIPTION OF THE DRAWINGS

In order to explain the embodiments of the present application more clearly, the following will briefly describe the drawings in the embodiments. It is obvious that the drawings in the following description are only some embodiments of the present application, for those skilled in the art, other drawings may be obtained from these drawings without creative work.

FIG. 1 is a flow chart of a charging reminder method for a rechargeable device according to an embodiment of the present application.

FIG. 2 is a schematic diagram of a mobile phone and a rechargeable device according to an embodiment of the present application.

FIG. 3 is a schematic diagram of a battery over-discharge point according to an embodiment of the present application.

### DETAILED DESCRIPTION OF THE PREFERRED EMBODIMENTS

The technical solutions in the embodiments of the present disclosure will be described clearly and completely below with reference to the drawings. The described embodiments are only a part of the embodiments of the present disclosure, and will not be limited. Based on the embodiments in the present disclosure, all other embodiments obtained by a person skilled in the art will fall within the protection scope of the present disclosure.

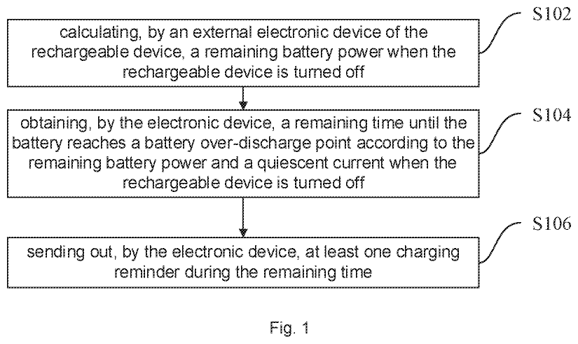

FIG. 1 shows a flowchart of a charging reminder method for a rechargeable device according to an embodiment of the present disclosure. As shown in FIG. 1, the charging reminder method includes the following steps:

S102: calculating, by an external electronic device of the rechargeable device, the remaining battery power when the rechargeable device is turned off.

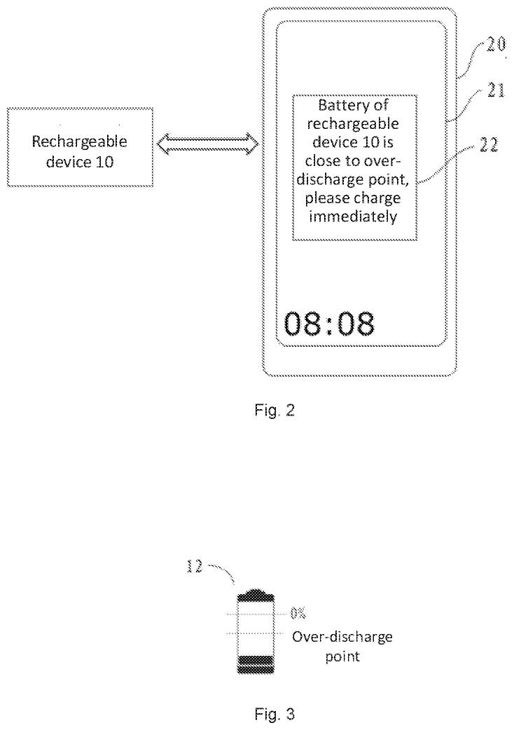

In an embodiment, the external electronic device may be a mobile phone that the user will carry with him/her at any time. In the following content, a mobile phone will be used as the external electronic device to illustrate various embodiments of the present disclosure, but it should be understood that the external electronic device may be any other applicable external electronic device. In some embodiments, the chargeable device may be a computer, a mobile communication device, and a consumption external electronic device, etc. FIG. 2 shows a schematic diagram of a mobile phone and a rechargeable device. As shown in FIG. 2, the mobile phone 20 and the chargeable device 10 communicate with each other wirelessly. In an embodiment, an application (APP) can be designed in the mobile phone 20, and the APP can communicate with the rechargeable device 10 to realize wireless communication between the mobile phone 20 and the rechargeable device 10, so that the mobile phone 20 can calculate the remaining battery power when the charging device 10 is turned off.

S104: obtaining, by the mobile phone 20, the remaining time until a battery of the rechargeable device reaches the over-discharge point according to the remaining battery power and the quiescent current when the rechargeable device 10 is turned off.

S106: sending out, by the mobile phone 20, at least one charging reminder during the remaining time. In some embodiments, the charging reminder is displayed on the display 21 of the mobile phone 20 in one or more manners of text, sound, picture, and light-emitting. In an embodiment, the APP in the mobile phone 20 will estimate the remaining time for the battery of the rechargeable device 10 to reach the over-discharge point, and continuously sends out a charging reminder at predetermined time intervals. For example, the mobile phone 20 pops-up reminder message 22 once a day on the display 21 of the mobile phone 20. In this case, the user will remember to charge the rechargeable device 10.

The charging reminder method provided in the present disclosure calculates the remaining power of the rechargeable device by an external electronic device of the rechargeable device, such as a mobile phone always carried by the user, and reminds the user the remaining time of the battery before reaching the over-discharge. The present disclosure can effectively remind the user to charge the rechargeable device that is not frequently used so as to avoid over-discharge of the battery.

In an embodiment, at step S102, before calculating the remaining battery power when the rechargeable device is turned off, the following steps may be performed to implement the communication between the mobile phone and the rechargeable device.

Calculating, by the rechargeable device, the power value of the battery, and providing the power value to the mobile phone in response to an acquisition request of the mobile phone when the rechargeable device is not turned off. In some embodiments, when the rechargeable device is not turned off, the mobile phone can send out at least one power value reminder based on the acquired power value. That is, when the rechargeable device communicates with the APP in the mobile phone, the rechargeable device detects and calculates its own power value, and the APP in the mobile phone regularly obtains the power value information provided by the rechargeable device. In addition, the APP can provide power information of rechargeable devices at any time, and can provide reminders when the power of the rechargeable device is low.

Determining that the rechargeable device is turned off when the mobile phone cannot obtain the power value. That is, when the rechargeable device is turned off and disconnected from APP in the mobile phone, and the mobile phone cannot obtain the power value information of the rechargeable device, step S102 is performed to automatically estimate the remaining battery power and remaining time of the battery.

Since the rechargeable device will have a quiescent current after being turned off (for example, the quiescent current is 0.05 mA), the quiescent current can be used to calculate the remaining time. Specifically, when the rechargeable device is turned off by the user, the power of the rechargeable device will be higher than that of auto shut off, for example, higher than 0% of the power auto shut off. At this time, when the rechargeable device is turned off, the remaining battery power and remaining time is calculated by the following steps.

When it is not possible to obtain the power information of the external device, the mobile phone automatically starts the power estimation function, and converts the power value obtained in the previous time to calculate the remaining battery power. In an embodiment, the previously acquired power value is a percentage of the power, and the remaining battery power of the battery can be converted from the percentage of the power. The remaining time is obtained by dividing the remaining battery power by the quiescent current.

When the battery of the rechargeable device reaches power-off level (for example, less than 0%) and turns off, the remaining battery power and remaining time before the rechargeable device is turned off can be calculated by the following steps.

When the power of the rechargeable device is less than 0% and the device is turned off, the mobile phone can start the APP automatic calculation function to automatically estimate the time before the battery of the rechargeable device reaches the over-discharge point, and continue to send out charging reminders. As shown in FIG. 3, after the power of the battery 12 reaches the power-off level (0%) and the rechargeable device is turned off, the battery 12 still has a certain power (for example, 100 mAhr) to reach the over-discharge point voltage (for example, 2.7 v). Then, the remaining time is obtained by dividing this remaining battery power (for example, 100 mAhr) by the quiescent current (for example, 0.05 mA). It should be understood that the calculated parameter values are different for different rechargeable devices.

The present disclosure further discloses a memory, which includes a program, and the program is executed by an external electronic device of a rechargeable device to implement the charging reminder method described above.

According to an embodiment of the present disclosure, the program is executed by an external electronic device of the rechargeable device to implement the following operations:

calculating, by the external electronic device, a remaining battery power when the rechargeable device is turned off;

obtaining, by the external electronic device, a remaining time until the battery of the rechargeable device reaches an over-discharge point according to the remaining battery power and a quiescent current when the rechargeable device is turned off;

sending out, by the external electronic device, at least one charging reminder during the remaining time.

The above-mentioned embodiments are only preferred embodiments of the present disclosure and are not intended to limit the present disclosure. Any modification, equivalent replacement, improvement, etc. made to the present disclosure within the principle of the present disclosure should be included in the protection scope of the present disclosure.

1. A charging reminder method for a rechargeable device, comprising:
calculating, by an external electronic device of the rechargeable device, a remaining battery power when the rechargeable device is turned off;
obtaining, by the external electronic device, a remaining time until a battery of the rechargeable device reaches a battery over-discharge point according to the remaining battery power and a quiescent current when the rechargeable device is turned off; and
sending out, by the external electronic device, at least one charging reminder during a remaining time.

2. The charging reminder method for a rechargeable device according to claim 1, wherein, when the rechargeable device is turned off at reaching a turning off power, the remaining battery power is the battery power from the turning off power to the battery over-discharge point, and
wherein the remaining time is a value obtained by dividing the remaining battery power by the quiescent current.

3. The charging reminder method for a rechargeable device according to claim 1, wherein, when the rechargeable device is turned off at a power level higher than the turning off power, the remaining battery power at the time of turning off is calculated according to a percentage of the battery power at a previous turning off of the rechargeable device, and
wherein the remaining time is a value obtained by dividing the remaining battery power by the quiescent current.

4. The charging reminder method for a rechargeable device according to claim 1, wherein, before calculating the remaining battery power when the rechargeable device is turned off, the method further comprises:
calculating, by the rechargeable device, a power value of the battery, and providing the power value to the external electronic device in response to an acquisition request of the external electronic device when the rechargeable device is not turned off; and
determining that the rechargeable device is turned off when the external electronic device cannot obtain the power value.

5. The charging reminder method for a rechargeable device according to claim 4, wherein, before calculating the remaining battery power when the rechargeable device is turned off, the method further comprises:
sending out, by the external electronic device, at least one power value reminder when the rechargeable device is not turned off.

6. The charging reminder method for a rechargeable device according to claim 1, wherein the charging reminder is displayed on the display screen of the external electronic device in one or more manners of text, sound, picture, and light-emitting.

7. The charging reminding method for a rechargeable device according to claim 1, wherein the external electronic device is a mobile phone, the mobile phone and the rechargeable device communicate with each other wirelessly.

8. A memory containing a program, wherein the program is executed by an external electronic device of a rechargeable device to implement the following operations:
calculating, by the external electronic device, a remaining battery power when the rechargeable device is turned off;
obtaining, by the external electronic device, a remaining time until a battery of the rechargeable device reaches an over-discharge point according to the remaining battery power and a quiescent current when the rechargeable device is turned off; and
sending out, by the external electronic device, at least one charging reminder during the remaining time.
